(19) United States
(12) Patent Application Publication
(10) Pub. No.: US 2012/0024363 A1
(43) Pub. Date: Feb. 2, 2012

(54) THIN FILM SOLAR CELL AND METHOD FOR PRODUCING IT

(75) Inventors: Martin DIMER, Dresden (DE); Tina SCHÖSSLER, Dresden (DE); Thomas KNOTH, Dresden (DE); Ralf STURM, Dresden (DE); Uwe GRAUPNER, Dresden (DE); Martin THUMSCH, Dresden (DE); Hans-Christian HECHT, Weinbohla (DE)

(73) Assignee: VON ARDENNE ANLAGENTECHNIK GMBH, Dresden (DE)

(21) Appl. No.: 13/195,433

(22) Filed: Aug. 1, 2011

(30) Foreign Application Priority Data
Aug. 2, 2010 (DE) 102010038796.7-33

(51) Int. Cl. H01L 31/06; H01L 31/18

(52) U.S. Cl. 136/255; 438/98; 257/E31.117

(57) ABSTRACT

A thin-film solar cell includes a front-side glass substrate, a front contact arranged above the glass substrate, an absorber arranged above the front contact, and a rear contact arranged above the absorber. A TCO layer system composed of an intrinsic TCO layer deposited above the substrate and a doped TCO layer arranged thereabove is provided, as well as a method for producing such a thin-film solar cell. Improved transmission, reflection and absorption properties of the TCO layer is achieved by composing the TCO layer of a first doped TCO sublayer deposited directly on the intrinsic TCO layer, and a second doped TCO sublayer deposited directly on the first doped TCO sublayer.

### CROSS REFERENCE TO RELATED APPLICATIONS

This application claims priority of German application no. 10 2010 038 796.7-33 filed on Aug. 2, 2010, the entire contents of which is hereby incorporated by reference herein.

### BACKGROUND ART

The invention relates to a thin-film solar cell comprising a front-side glass substrate, a front contact arranged above the glass substrate, an absorber arranged above the front contact, and a rear contact arranged above the absorber. A TCO layer system composed of an intrinsic TCO layer deposited above the substrate and a doped TCO layer arranged thereabove is provided in said solar cell. The invention also relates to a method for producing a thin-film solar cell, in which a layer of a front contact is deposited above a front-side glass substrate, a layer as absorber is deposited above the front contact, and a rear contact is deposited above the absorber. In this case, a TCO layer system composed of an intrinsic TCO layer deposited above the substrate and a doped TCO layer arranged thereabove is deposited in the layer system.

Solar cells are manufactured as so-called thin-film cells or thin-film solar cells. The latter consist of a fully transparent substrate, in particular composed of glass, to which a photoactive layer stack is applied. In the following description, the layer stack is established above the substrate. In this case, the presentation relates to establishing the layer stack on that side of the substrate which lies opposite the light entrance side, wherein the substrate lies with its side that faces the light entrance at the bottom.

Photovoltaic components as thin-film solar cells in the form of a-Si/μc-Si cells are described in DE 197 13 215 A1.In that case, a substrate, which is generally glass, is provided, if appropriate on intervening barrier or seed layers, with a TCO layer on which a layer sequence composed of amorphous and microcrystalline silicon is arranged.

One important requirement made of the layers in photovoltaics is high scattering of the light into the absorbing cell. The scattering brings about an effective lengthening of the path length covered in the absorber and hence a higher probability of absorption of the incident light in conjunction with a reduced absorber thickness.

Optimum transmission, conductivity, reflection and absorption are required in the case of a TCO layer. In this case, action is needed for improvement in the prior art.

One effort for improvement or optimization can be discerned in US 2009/0126791 A1,wherein the TCO layer (TCO=transparent conductive oxide), which realizes the electrode and the scattering layer as essential function, is constructed in a multilayered fashion, wherein a substrate-side layer sequence composed of intrinsic TCO and silver is succeeded by a doped TCO layer arranged thereon.

### BRIEF SUMMARY OF THE INVENTION

The invention is based on the aspect of improving the properties of the TCO layer in terms of its properties: transmission, reflection and absorption.

This aspect is achieved by a thin-film solar cell and method comprising the features and refinements of the present invention.

### BRIEF SUMMARY OF THE DRAWING FIGURES

The invention will be explained in greater detail below on the basis of an exemplary embodiment. In the associated drawings:

FIG. 1 shows a schematic cross section through the layers of a thin-film solar cell according to the invention which are near the substrate and are relevant to the invention,

FIG. 2 shows the transmission, reflection and absorption spectra of an AZO layer on glass substrate, and

FIG. 3 shows the transmission, reflection and absorption spectra of the same AZO layer deposited in the same coating process but on a glass substrate coated with i-ZnO.

### DETAILED DESCRIPTION

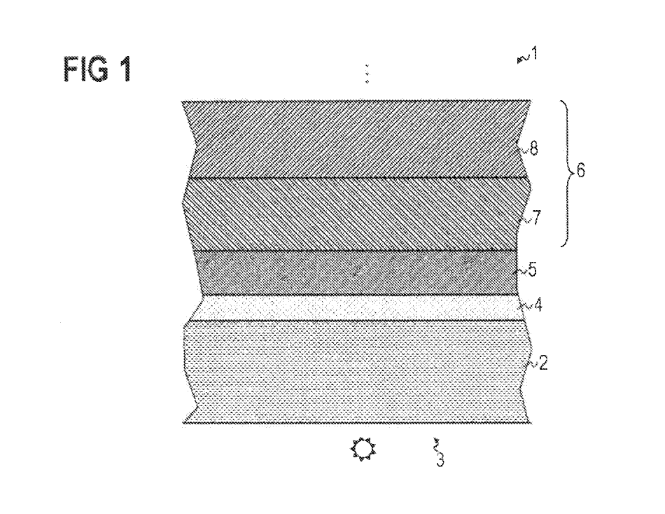

As illustrated in FIG. 1, the thin-film solar cell 1 has a glass substrate 2. The sun symbol denotes the front side 3, that is to say the light entrance side.

On that surface of the glass substrate 2 which faces away from the light entrance 3, an insulating barrier layer 4 is arranged above the glass substrate 2. Said barrier layer can consist of Si₃N₄, for example. An intrinsic TCO layer, in this example an intrinsic ZnO layer 5, is deposited thereabove. A doped TCO layer 6 is situated thereabove. The absorber system, a rear contact and possibly a protective substrate are then provided thereabove, which, for the sake of better clarity, are indicated by three dots, but not illustrated in greater detail. The TCO layer 6 itself is embodied in two-layered fashion. It consists of a first doped TCO sublayer in the form of a ZnO-A layer 7 deposited directly on the intrinsic TCO layer, the ZnO layer 5, and of a second doped TCO sublayer in the form of a ZnO-B layer 8, where “A” and “B” are intended to designate different dopants and/or doping concentrations.

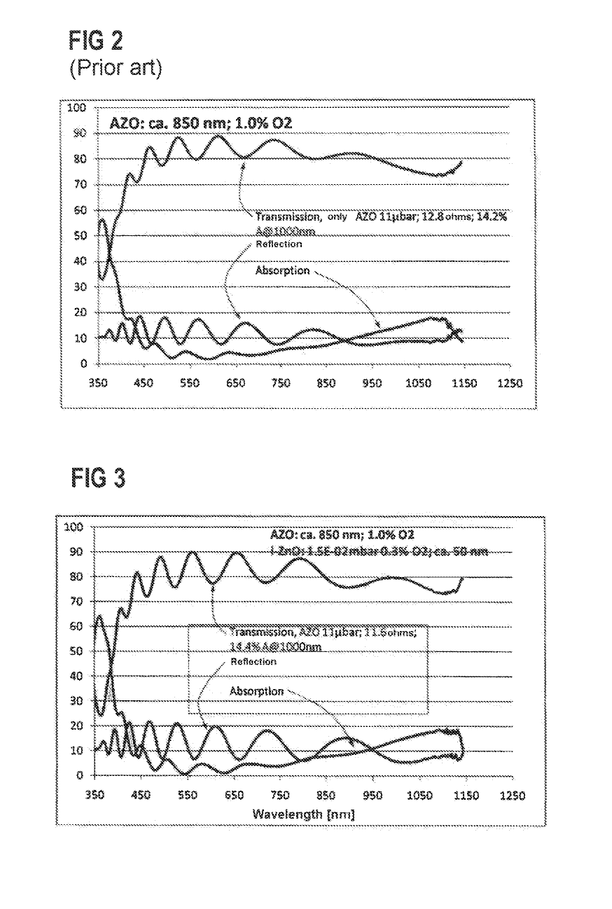

FIG. 2 shows the transmission, reflection and absorption spectra of an AZO layer (AZO=aluminium zinc oxide) on a glass substrate according to the prior art. This is contrasted by way of FIG. 3, with the transmission, reflection and absorption spectra of an AZO layer configured according to the invention on a glass substrate 2 coated with an i-ZnO layer. In this case, it emerges that, by means of a layer sequence composed of a thin i-ZnO layer 5 and a doped 2-layered TCO layer 6 in the form of an AZO layer, the properties of the overall layer system, namely the absorption of the overall layer system, the sheet resistance and the maximum transmission and also the difference between the interference maximum and the subsequent interference minimum of the transmission are increased.

1. Thin-film solar cell comprising a front-side glass substrate, a front contact arranged above the glass substrate, an absorber arranged above the front contact, and a rear contact arranged above the absorber, said solar cell having a TCO layer system composed of an intrinsic TCO layer deposited above the substrate and a doped TCO layer arranged above the intrinsic TCO layer, wherein the doped TCO layer comprises a first doped TCO sublayer deposited directly on the intrinsic TCO layer, and a second doped TCO sublayer deposited directly on the first doped TCO sublayer.

2. Thin-film solar cell according to claim 1, wherein the TCO layer system comprises ZnO layers.

3. Thin-film solar cells according to claim 1, wherein the first and second TCO sublayers have a different degree of doping and/or different doping elements than each other.

4. Thin-film solar cell according to claim 1, wherein averaged absorption in a wavelength range of between 450 and 1100 nm of the TCO layer comprising the two sublayers is lower in comparison with a layer system without the second sublayer.

5. Thin-film solar cell according to claim 1, wherein at least one SiOₓN_{y}, one SiOₓ, or one SiₓN_{y} layer where 0<×≦2 and 1≦<y≦2 is incorporated between the intrinsic TCO layer and the substrate.

6. Thin-film solar cell according to claim 1, wherein the first and/or the second doped TCO sublayer is doped with at least one of the elements Al, In, Ga, F, Y, Mg or boron.

7. Method for producing a thin-film solar cell, comprising: depositing a layer of a front contact above a front-side glass substrate, depositing an absorber layer above the front contact, and depositing a rear contact above the absorber layer, depositing a TCO layer system above the substrate, the TCO layer system comprising a doped TCO layer arranged above an intrinsic TCO layer, and wherein a first doped TCO sublayer of the doped TCO layer is deposited directly on the intrinsic TCO layer and a second doped TCO sublayer of the doped TCO layer is deposited directly on the first doped TCO sublayer.

8. Method according to claim 7, wherein the TCO layer system comprises ZnO layers.

9. Method according to claim 8, wherein the ZnO layers are deposited by DC, DC pulse or MF sputtering of tubular targets.

10. Method according to claim 7, wherein the first and second TCO sublayers are deposited with a different degree of doping and/or different doping elements than each other.

11. Method according to claim 7, wherein at least one SiOₓN_{y}, one SiOₓ or one SiₓN_{y} layer where 0<×≦2 and 1≦<y≦2 is deposited between the intrinsic TCO layer and the substrate.

12. Method according to claim 7, wherein the first and/or the second doped TCO sublayer is doped with at least one of the elements Al, In, Ga, F, Y, Mg or boron.
